(19) United States
(12) Patent Application Publication
(10) Pub. No.: US 2017/0125531 A9
(43) Pub. Date: May 4, 2017

(54) THICKER BOTTOM OXIDE FOR REDUCED MILLER CAPACITANCE IN TRENCH METAL OXIDE SEMICONDUCTOR FIELD EFFECT TRANSISTOR (MOSFET)

(71) Applicants: Yeeheng Lee, San Jose, CA (US); Xiaobin Wang, San Jose, CA (US)

(72) Inventors: Yeeheng Lee, San Jose, CA (US); Xiaobin Wang, San Jose, CA (US)

(21) Appl. No.: 14/171,777

(22) Filed: Feb. 4, 2014

Related U.S. Application Data
(63) Continuation-in-part of application No. 13/560,247, filed on Jul. 27, 2012, now Pat. No. 9,000,514.
Application No. 13/560,247 is a division of application No. 12/551,417, filed on Aug. 31, 2009, now Pat. No. 8,252,647.

(51) Int. Cl. H01L 29/423; H01L 29/51; H01L 29/78; H01L 21/321; H01L 21/28; H01L 21/311; H01L 21/033; H01L 21/02; H01L 29/49; H01L 29/66

(52) U.S. Cl. CPC H01L 29/4236; H01L 29/4916; H01L 29/51; H01L 29/7813; H01L 29/66734; H01L 21/28035; H01L 21/31111; H01L 21/0332; H01L 21/0217; H01L 21/02164; H01L 21/02238; H01L 21/3212

(57) ABSTRACT

Semiconductor device fabrication method and devices are disclosed. The semiconductor power device is formed on a semiconductor substrate having a plurality of trench transistor cells each having a trench gate. Each of the trench gates having a thicker bottom oxide (TBO) formed by a REOX process on a polysilicon layer deposited on a bottom surface of the trenches.

### CROSS-REFERENCE TO RELATED APPLICATION

### Priority Claim

This application is a Continuation-in-Part (CIP) application and claims the priority benefit of a co-pending application Ser. No. 13/560,247 filed on Jul. 27, 2012. Application Ser. No. 13/560,247 is a Divisional application of Ser. No. 12/551,417 filed on Aug. 31, 2009 and now issued as U.S. Pat. No. 8,252,647. The disclosures made in application Ser. Nos. 12/551,417 and 13/560,247 are hereby incorporated by reference in the present patent application.

### FIELD OF THE INVENTION

This invention generally relates to the methods and configuration for fabricating a trench semiconductor power device, e.g., a DMOS device, and more particularly to the device configurations and methods for fabricating a trench semiconductor power device with variable-thickness gate oxides.

### DESCRIPTION OF THE RELATED ART

A DMOS (Double diffused MOS) transistor is a type of MOSFET (Metal Oxide Semiconductor Field Effect Transistor) that uses two sequential diffusion steps aligned to a common edge to form a channel region of the transistor. DMOS transistors are often implemented as a high voltage, high current device as discrete transistors or as components in power integrated circuits. The advantage of such applications is because the DMOS transistors can provide high current per unit area with a low forward voltage drop.

One particular type of DMOS transistor is a trench DMOS transistor. In this type of DMOS transistor, the gate is formed in a trench and the channel is formed around the sidewalls of the trench gate and the channel extends from the source towards the drain. The trench gate is lined with a thin oxide layer and filled with polysilicon. Compared with a planar gate DMOS device, the trench DMOS allows less constricted current to flow and thereby provides lower values of specific on-resistance.

In order to improve the device performance, it is often necessary to allow flexibility in the manufacturing processes to more conveniently fabricate a trench DMOS transistor to adjust the thickness of the trench oxide. The device performance is improved by strategically adjusting the thickness of the gate oxide at different portions inside the trench. Specifically, a thinner gate oxide is preferred at the upper portion of the trench to maximize channel current. By contrast, a thicker gate oxide is desired at the bottom portion of trench to support higher gate-to-drain breakdown voltage.

U.S. Pat. No. 4,941,026 discloses a vertical channel semiconductor device including an insulated gate electrode having a variable thickness oxide, but does not illustrate how to make such a device.

U.S. Pat. No. 4,914,058 discloses a process for making a DMOS, including lining a groove with a nitride to etch an inner groove having sidewalls extending through the bottom of the first groove, and lining the inner groove with a dielectric material by oxidation growth to obtain increased thickness of the gate trench dielectric on the sidewalls of the inner groove.

US publication No. 2008/0310065 discloses a transient voltage suppressing (TVS) circuit with uni-directional blocking and symmetric bi-directional blocking capabilities integrated with an electromagnetic interference (EMI) filter supported on a semiconductor substrate of a first conductivity type. The TVS circuit integrated with the EMI filter further includes a ground terminal disposed on the surface for the symmetric bi-directional blocking structure and at the bottom of the semiconductor substrate for the uni-directional blocking structure and an input and an output terminal disposed on a top surface with at least a Zener diode and a plurality of capacitors disposed in the semiconductor substrate to couple the ground terminal to the input and output terminals with a direct capacitive coupling without an intermediate floating body region. The capacitors are disposed in trenches having an oxide and nitride lining.

A difficulty arises during polysilicon gate backfill in the trench if a thick oxide is uniformly formed in the trench, producing a higher trench aspect ratio (ratio of depth A to width B) as shown in the prior art. By way of example, FIGS. 1A-1D are cross-sectional views illustrating a prior art method of forming a single gate of the prior art. As shown in FIG. 1A, a trench 106 is formed in a semiconductor layer 102. A thick oxide 104 is formed on the bottom and sidewalls of the trench 106 which increases its aspect ratio A/B. Polysilicon 108 is in-situ deposited into the trench 106. Due to the high aspect ratio of the polysilicon deposition, a keyhole 110 tends to form as shown in FIG. 1B. As shown in FIG. 1C, the poly 108 is etched back followed with an isotropic high temperature oxidation (HTO) oxide etch as shown in FIG. 1D, throughout which a portion of the keyhole 110 remains.

FIG. 2 is a cross-sectional view of a current shield gate trench (SGT) device 200 having a shield poly gate with an Inter-Poly Oxide (IPO) 202 between a first polysilicon structure that forms a gate 204 and a second polysilicon structure 206 that acts as a conductive shield. According to one prior art process, such a structure is formed by a process that involves two etch-back steps (of the polysilicon layer 206 and of the IPO oxide layer 202) in forming the IPO 202 between the two polysilicon structures 204, 206. Specifically, the polysilicon that forms the shield 206 is deposited in the trench and etched back and HDP oxide is formed on the shield 206 and etched back to make room for deposition of the polysilicon that forms the gate structure 204. This approach has the drawback of poor IPO thickness controllability across wafer. The IPO thickness depends on two independent and unrelated etch-back steps, which could cause non-uniform and local thinning of IPO thickness due to either under etch-back of Poly or over etch-back of Oxide or a combination of both.

Also, in the methods discussed above the thickness of the gate trench dielectric on the thick portion of the side wall versus the thickness at the bottom of the trench are linked together. One thickness cannot be altered without affecting the other thickness.

For the above reasons, there is a need to provide new device configurations and new manufacturing methods for the semiconductor power devices to provide more convenient manufacturing processes to more flexibly adjust the gate oxide thickness along different parts of the trench gates such that the above discussed technical difficulties and limitations can be resolved.

### SUMMARY OF THE PRESENT INVENTION

It is an aspect of the present invention to provide a new and improved device configuration and manufacturing method for providing a semiconductor power device with reduced gate to drain capacitance by adjusting the gate oxide thickness, especially, the thickness of the trench bottoms for trenches with a high aspect ratio.

Another aspect of the present invention is to provide a new and improved device configuration and manufacturing method for providing a semiconductor power device with reduced gate to drain capacitance for high density transistor cells manufactured with trench gates having high aspect ratios. The improved processes provide simplified and low cost processing steps to fabricate thicker bottom oxide (TBO) trenches for high density transistor cells such that the difficulties and imitations encounter by the conventional manufacturing processes can be resolved to produce improved device performance.

Briefly in a preferred embodiment this invention discloses a semiconductor power device formed on a semiconductor substrate having a plurality of trench transistor cells each having a trench gate. Each of the trench gates having a thicker bottom oxide (TBO) formed by a Poly REOX process on a polysilicon layer deposited on a bottom surface of the trenches.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIGS. 1A-1D are cross-sectional schematic diagrams illustrating trench gate fabrication according to the prior art.

FIG. 2 is a cross-sectional schematic diagram of a trench gate including an inter-poly oxide (IPO) between Poly1 and Poly2 of the prior art.

FIGS. 3A-30 are cross-sectional views illustrating a process of fabricating a trench DMOS with variable-thickness gate trench oxides for single poly gate case according to an embodiment of the present invention.

FIGS. 4A-4M are cross-sectional views illustrating a process of fabricating a trench DMOS with variable-thickness gate trench oxides for shield poly gate case according to an embodiment of the present invention.

FIGS. 5A-5F are cross-sectional views illustrating an alternative process of fabricating a trench DMOS with variable-thickness gate trench oxides for shield poly gate case according to an embodiment of the present invention.

FIGS. 6A to 6F are cross-sectional views illustrating an alternative process of fabricating a trench DMOS with a thicker bottom oxide (TBO) for shield poly gate according to an embodiment of the present invention.

### DETAILED DESCRIPTION OF THE PREFERRED EMBODIMENTS

In embodiments of the present invention as illustrated below, separated processing steps are applied to make the bottom dielectric layer to have a greater thickness than the dielectric layer on the trench sidewalls A thicker bottom dielectric layer reduces the capacitance between the trench gate and the drain of the DMOS transistors.

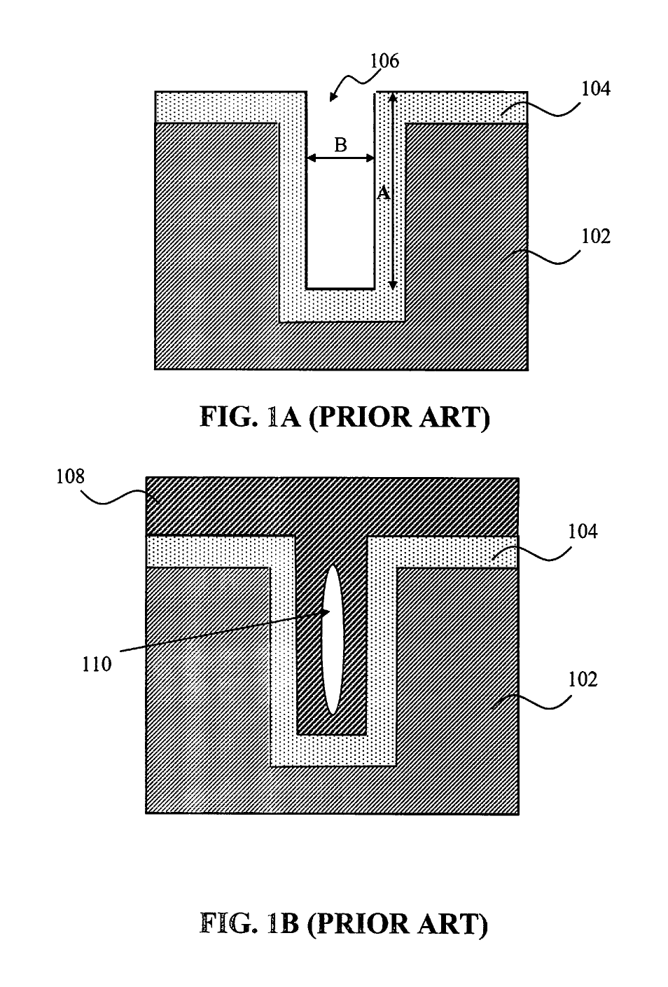

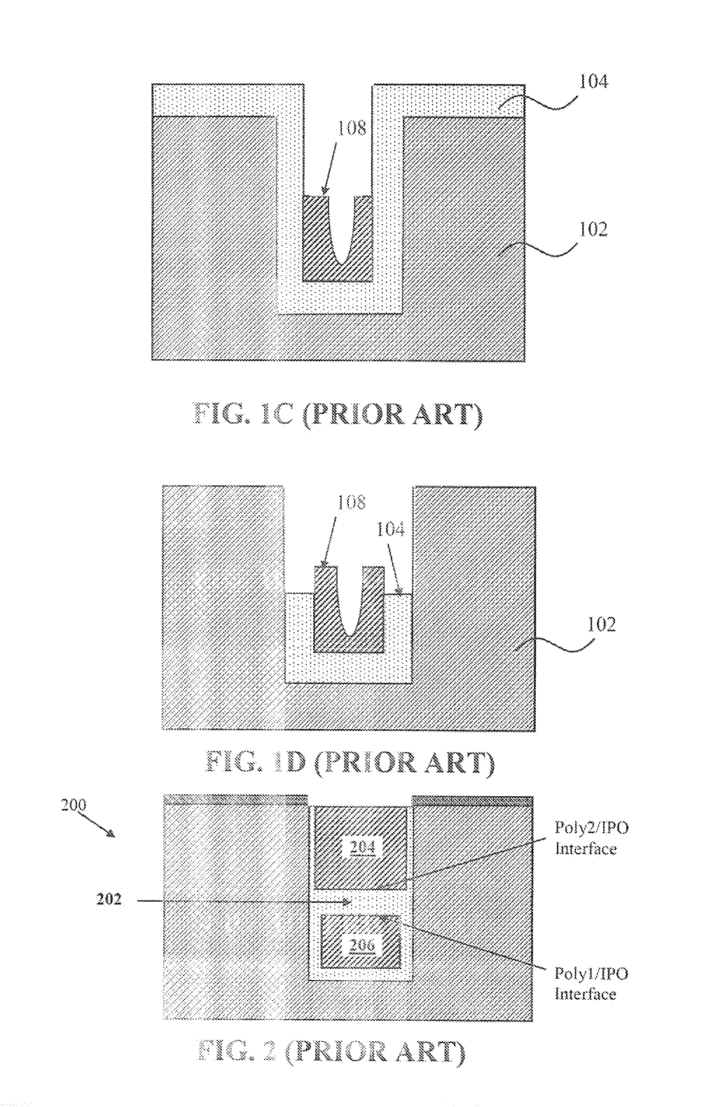

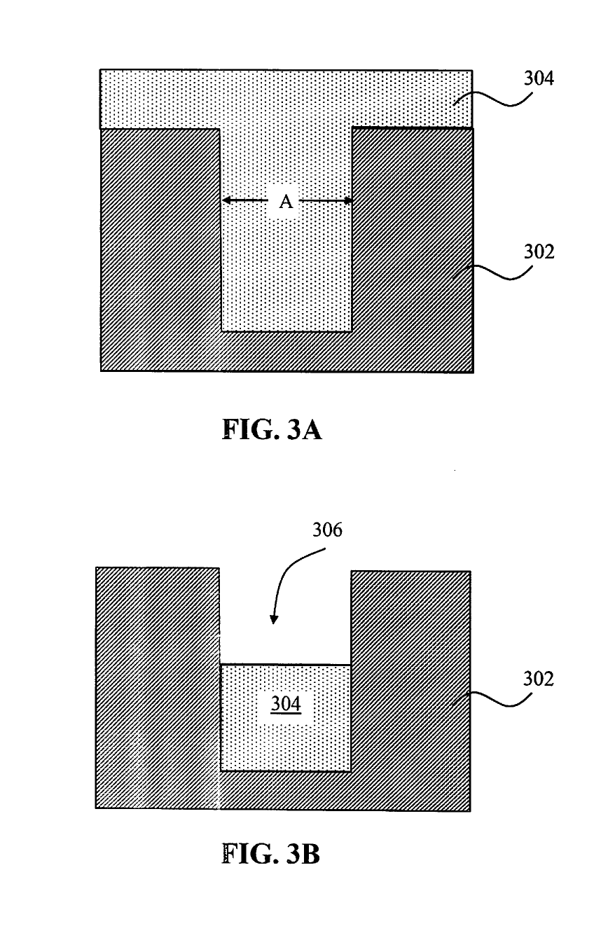

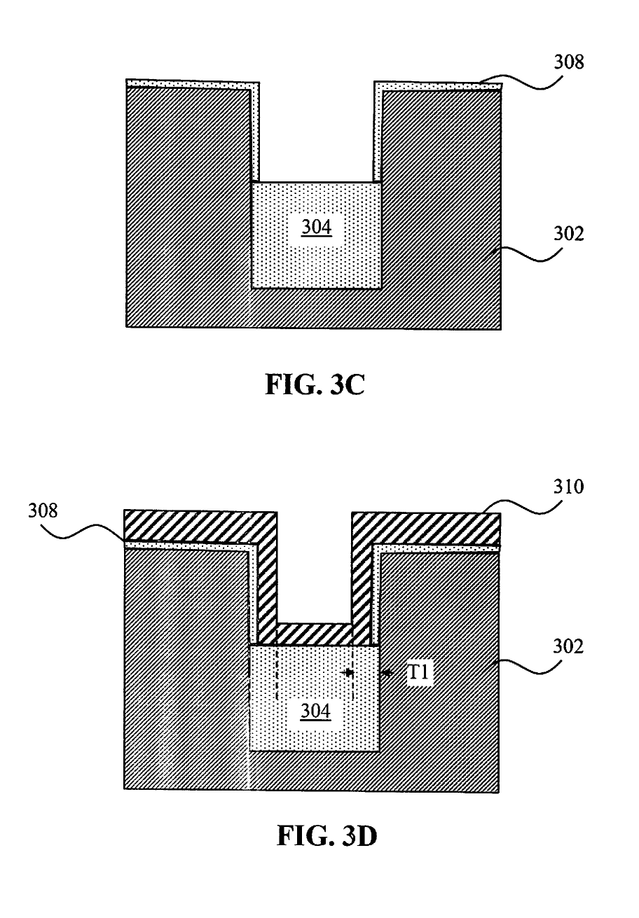

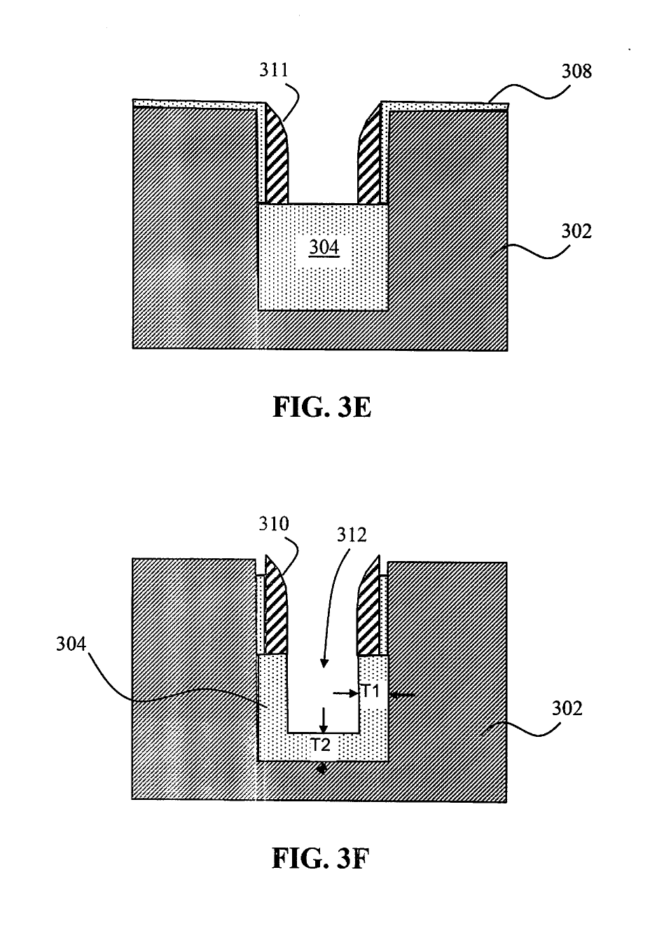

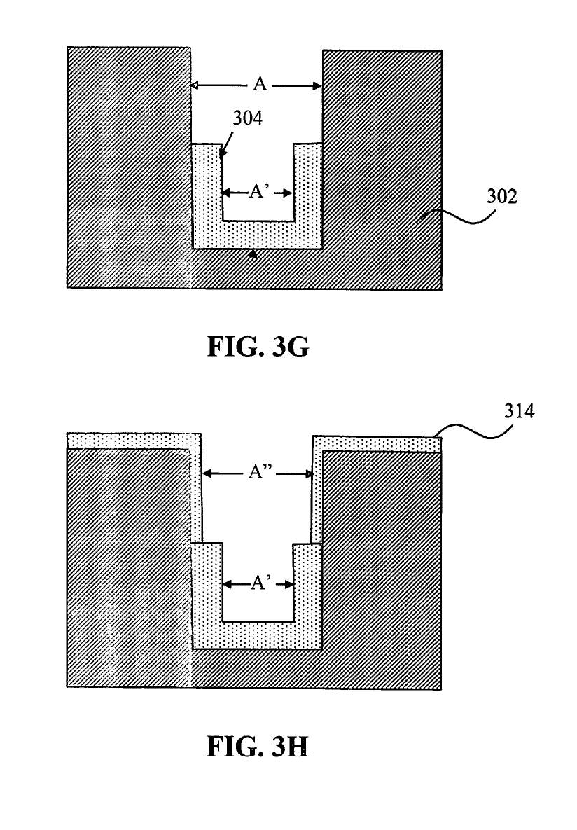

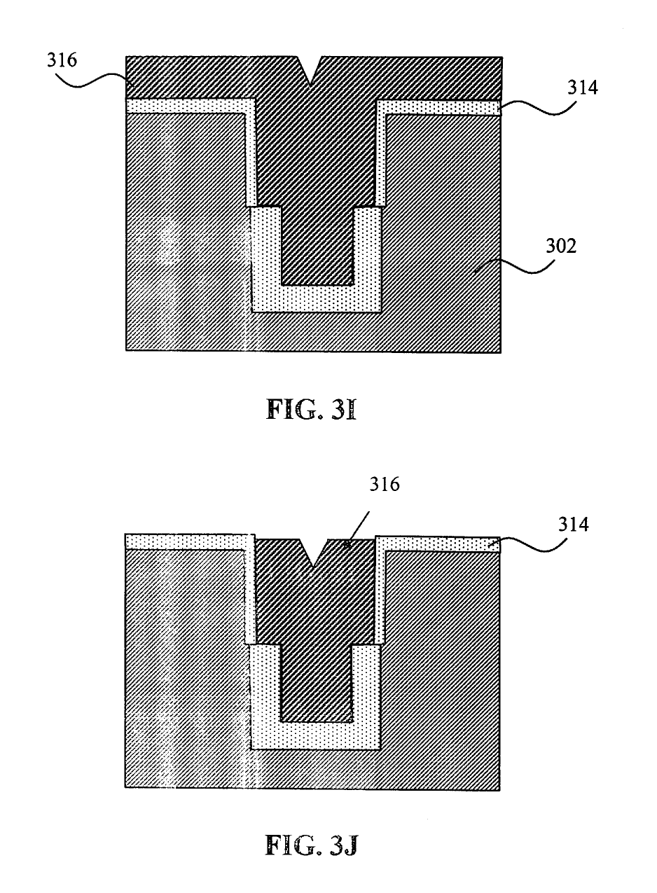

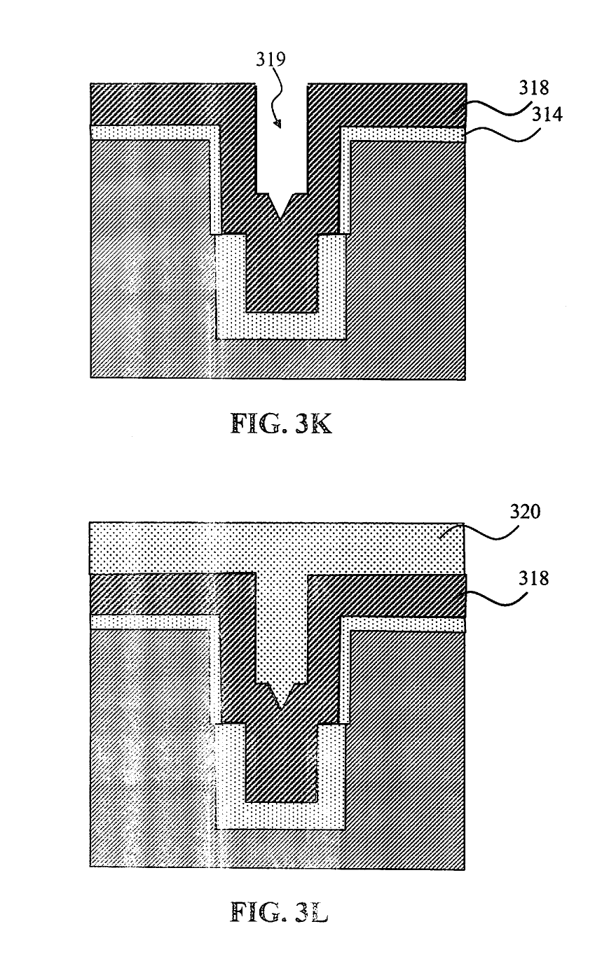

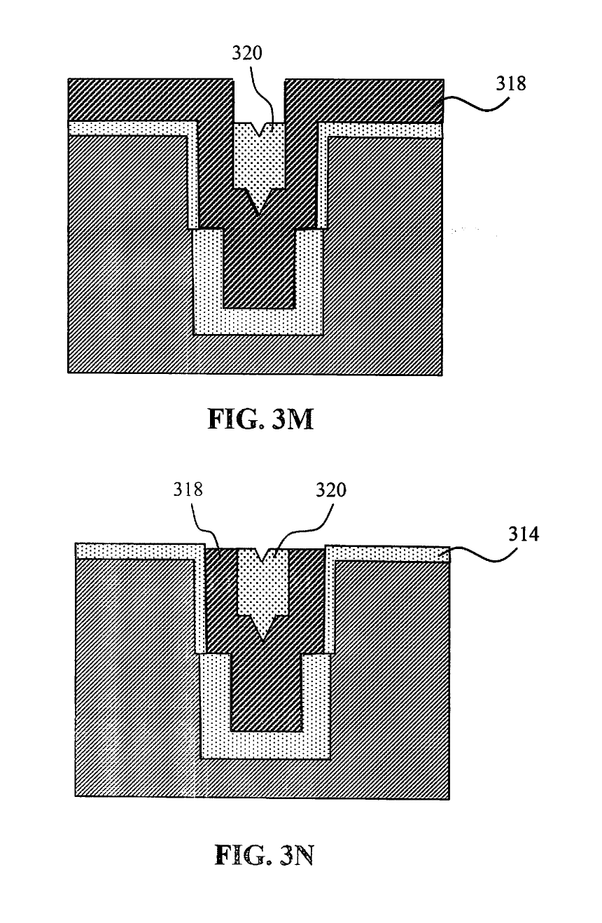

FIGS. 3A to 3O are cross-sectional views illustrating the fabrication process steps for manufacturing a trench DMOS with variable-thickness trench gate oxides for a single polysilicon (poly) gate of the type depicted in FIG. 1D according to an embodiment of the present invention.

As shown in FIG. 3A, a trench 306 of width A is formed in a semiconductor substrate 302. By way of example and not by way of limitation, the trench 306 is formed by applying a hard mask (not specifically shown), e.g., oxide or nitride, which may then be removed or left in place. Alternatively, the trench 306 may also be formed by applying using a photoresist (PR) mask (not shown). An oxide 304 (or other insulator) is deposited to fill the trench 306. A chemical mechanical planarization (CMP) is carried out on the oxide 304 followed by an etching back to recess the oxide 304 in the trench 306 as shown in FIG. 3B, leaving an thick block of the oxide 304 filling a substantially portion of the lower part of the trench and exposing the silicon sidewall of upper portion of the trench. In FIG. 3C, a thin oxide 308 is then grown on the exposed sidewall of the trench 306 and on the top surface of the semiconductor substrate 302. By way of example, and not by way of limitation, the thickness of the thin oxide 308 has a range between about 50 Angstroms to 100 Angstroms.

FIG. 3D shows a step of depositing a layer of oxide etch resistant material, such as nitride 310, on top of the oxide 308 and the oxide 304. In an exemplary embodiment, the nitride 310 may composed of a silicon nitride. Alternatively, the etch resistant layer 310 may compose of a polysilicon layer since the polysilicon layer also has high etch resistance during subsequent oxide etch. The thickness of the nitride 310 determines the bottom oxide sidewall thickness T1, which may be between about 500 angstroms and about 5000 angstroms. The nitride 310 is then anisotropically etched back leaving one or more oxide etch resistant spacers 311 on the sidewall of the trench 306 as shown in FIG. 3E. The thick oxide block 304 may then be anisotropically etched to a predetermined thickness T2 at the bottom of the trench 306 as shown in FIG. 3F. The thickness T2 may be between about 500 angstroms and about 5000 angstroms. The material such as a nitride material that forms the spacer(s) 311 is preferably resistant to the process used to etch the oxide 304. The spacer(s) 311 therefore act as an etch mask to define a width A′ of a trench etched into the oxide 304. In this method, the thicknesses T1 and T2 are decoupled, i.e., the thickness T1 does not depend on the thickness T2. In general, it is desirable for T2 to be greater than T1. This may be accomplished more easily if the thicknesses T1 and T2 are decoupled. After etching, the spacers 311 and thin oxide 308 may be removed leaving behind a trench with a top portion of width A and a narrower bottom portion of width A′ lined by the remaining portion of oxide 304 as shown in FIG. 3G.

Gate oxide (or dielectric) 314 may then be grown on top of the semiconductor substrate 302 and on portions of the sidewall of the trench that are not covered by the remaining oxide 304 leaving the top portion with a width A″ that is greater than the width A′ of the bottom portion as shown in FIG. 3H. The trench “aspect ratio” is effectively reduced for easier filling due to the wide trench top portion having width A″. Conductive material, such as doped polysilicon may then be deposited to fill the trench. FIG. 3I shows the polysilicon gap fill 316 in a narrow trench case, e.g., where the width A″ at the top of the trench is about 1.2 microns, where the doped polysilicon can easily fill up the trench completely. The polysilicon 316 is then etched back to form a single gate poly as shown in FIG. 3J. The polysilicon 316 acts with the gate dielectric 314 as the gate electrode for the device.

Alternatively, FIG. 3K shows the poly gap fill 318 in the wider trench case, e.g., the diameter A″ at the top of the trench is about 3 microns, where poly cannot easily fill up completely, which leaves a gap 319. A filler material, such as an HDP oxide 320, may then be deposited to fill the gap 319 and on top of the poly 318 as shown in FIG. 3L. The filler material 320 may then be etched back as shown in FIG. 3M followed by an etching back of the poly 318 and filler material 320 to form a single gate poly 318 as shown in FIG. 3N. The device may be completed by a standard process e.g., involving ion implant into selected portions of the semiconductor substrate 302 to form a body region 330 and source regions 332, followed by the formation of a thick dielectric layer 360 on top of the surface and open contact holes through dielectric layer 360 for depositing a source metal 370 to electrically connect to the source and body regions as shown in FIG. 3O.

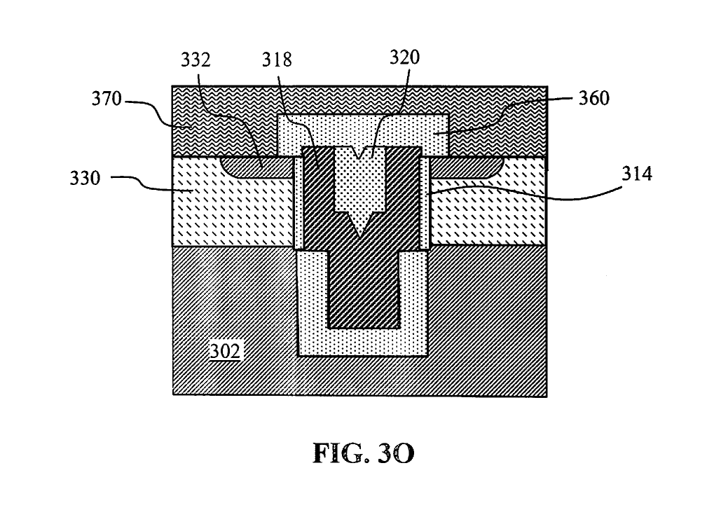

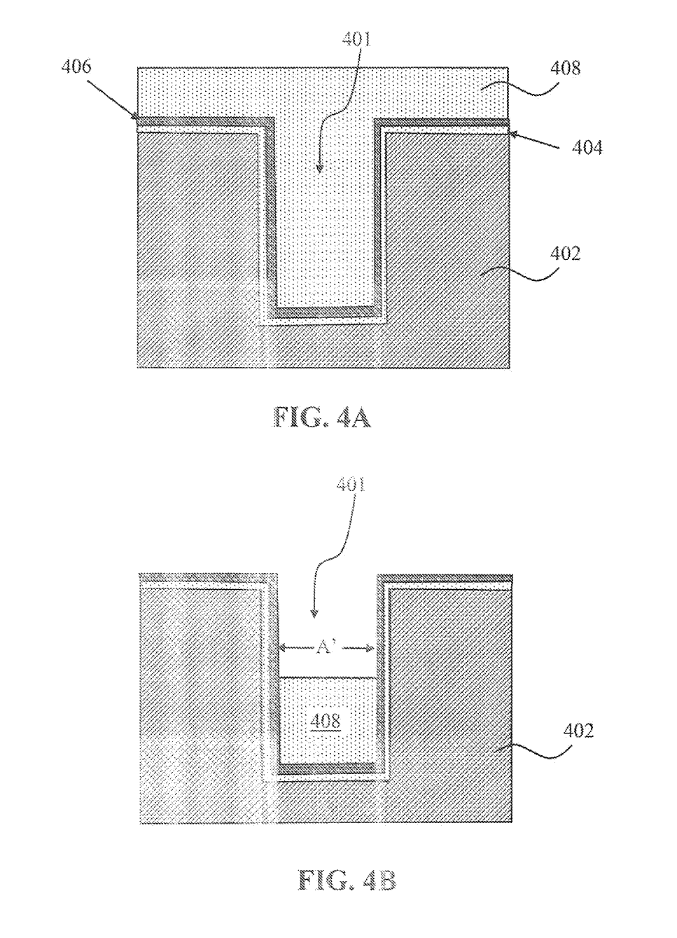

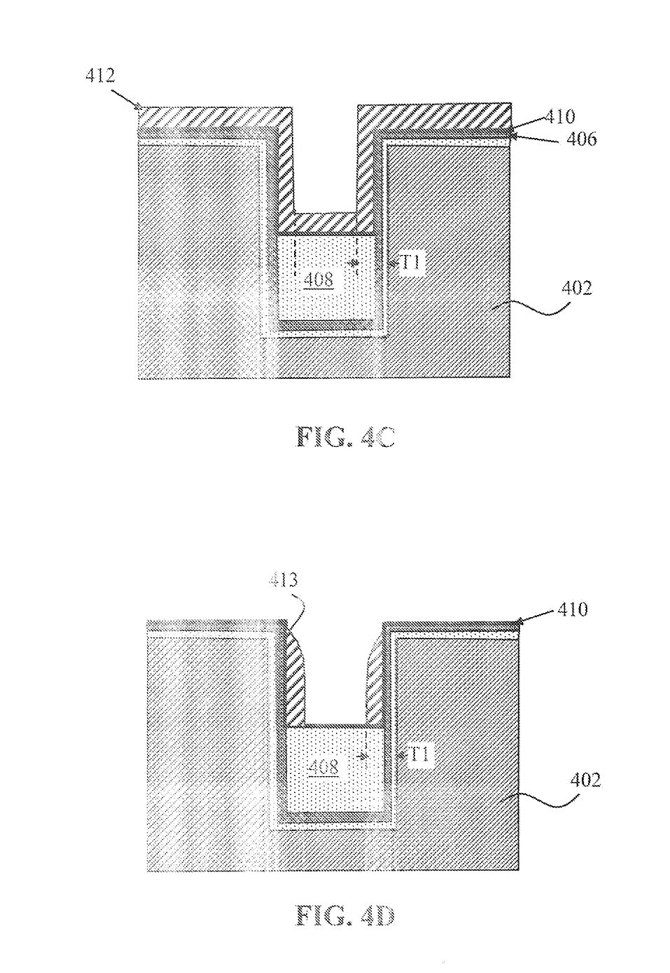

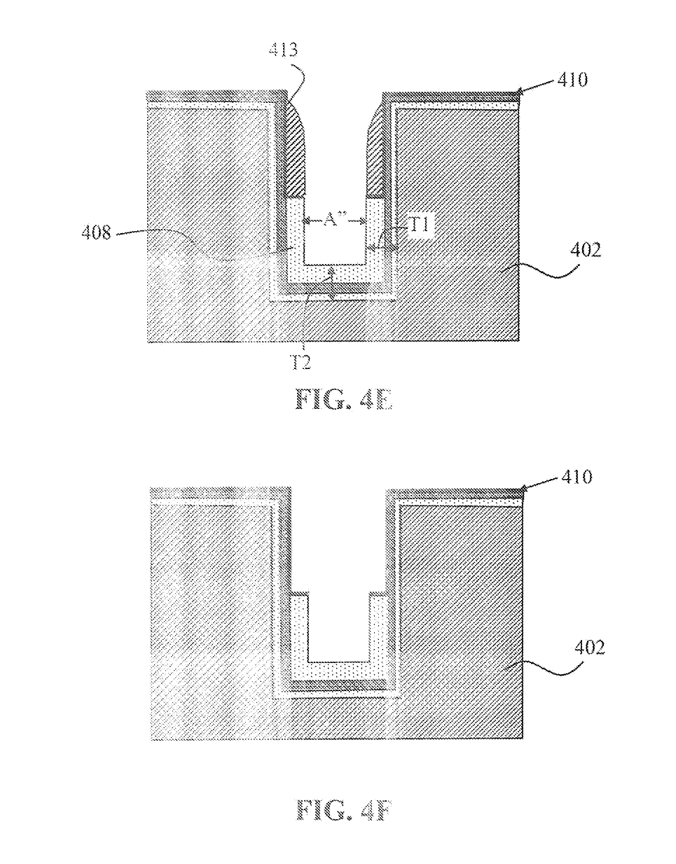

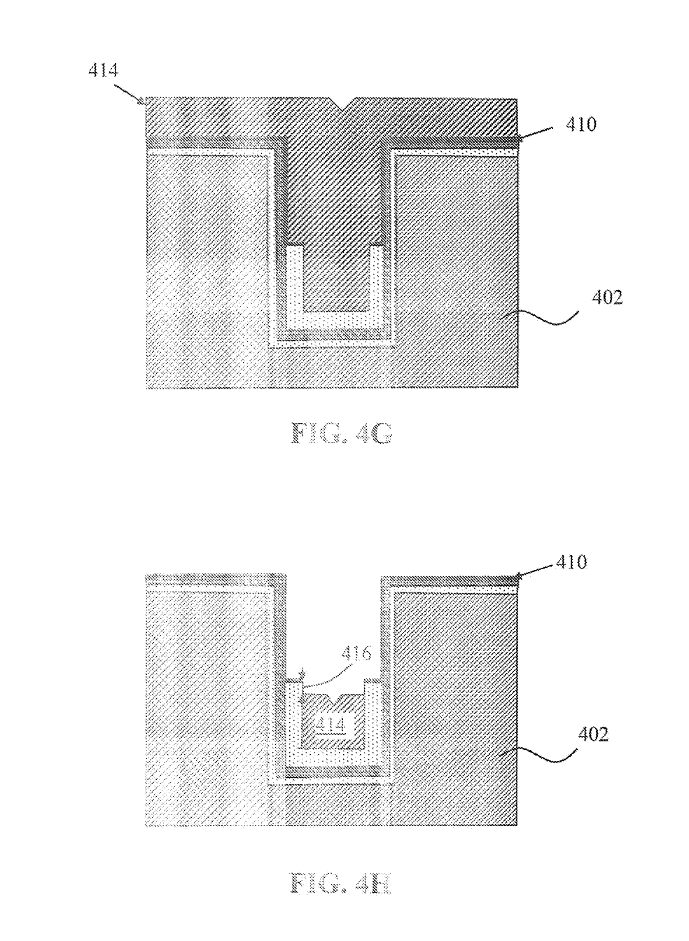

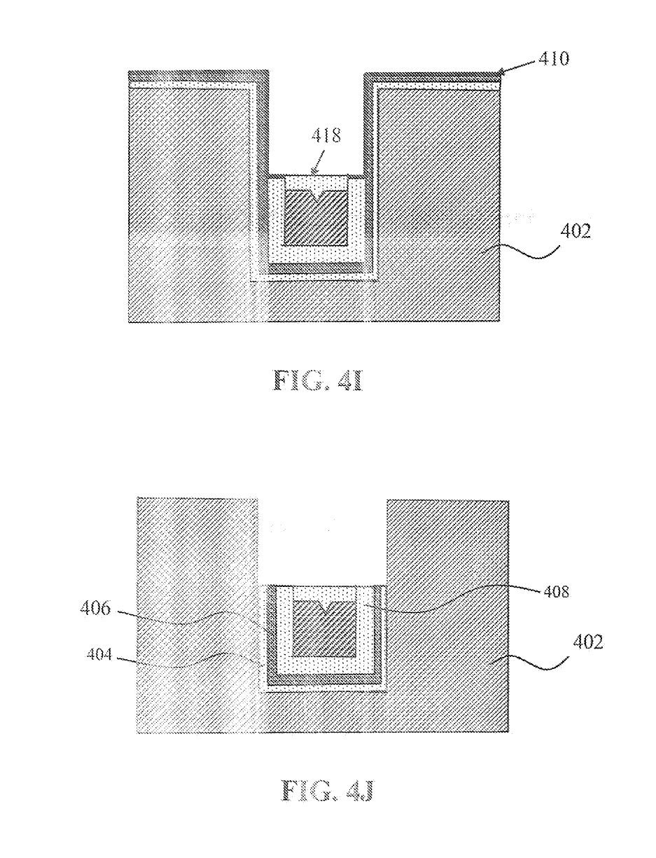

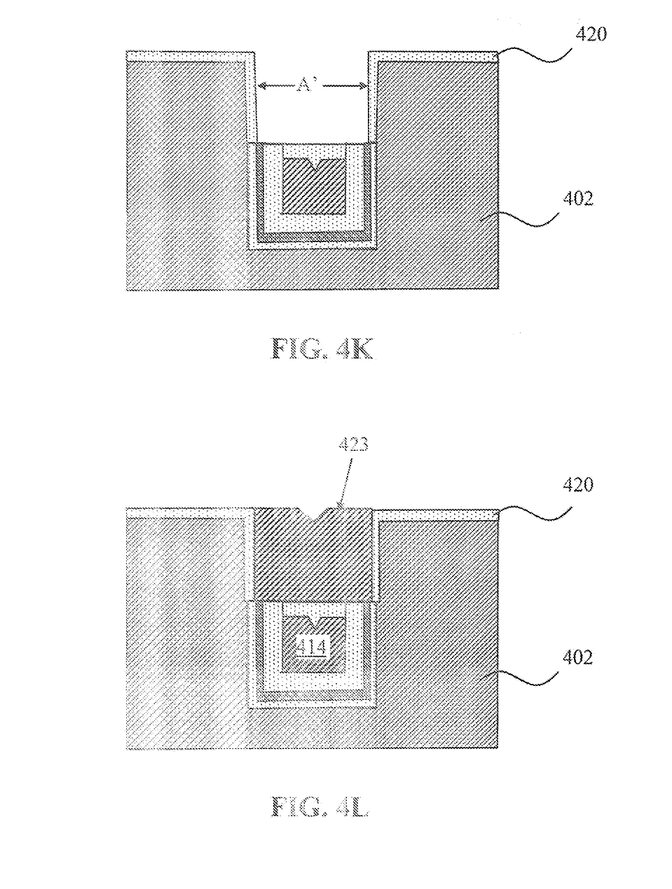

There are a number of variations on the process described above that are within the scope of embodiments of the present invention. For example, FIGS. 4A-4M illustrate a process to fabricate a trench DMOS with variable-thickness gate trench oxides for a shield poly gate of the type depicted in FIG. 2 according to an embodiment of the present invention. In this embodiment, a composite insulator in the form of an oxide-nitride-oxide (ONO) structure is formed on the sidewall and the bottom of the trench.

As shown in FIG. 4A, a trench 401 is first formed in a semiconductor substrate 402. A thin oxide layer 404 is formed on the sidewall of the trench 401. The thickness of the oxide layer 404 may be between about 50 Angstroms and 200 Angstroms. Nitride 406 is then deposited on top of the oxide layer 404. Thickness of the nitride layer 406 may be between about 50 Angstroms and 500 Angstroms. The trench 401 may then be filled with oxide 408, e.g., using LPCVD and high density plasma. The oxide 408 may then be etched back leaving a trench of width A with thick oxide block substantially filling the tower portion of the trench as shown in FIG. 4B.

A thin oxide layer 410 (e.g., a high temperature oxide (HTO)) may optionally be deposited on top of the oxide 408, on the sidewall of the trench 401 and on top of the nitride 406 as shown in FIG. 4C. The thickness of the oxide 410 may be between about 50 Angstroms and 500 Angstroms. Conductive material, such as doped polysilicon 412 may then be deposited on top of the oxide 410 (or on the nitride 406 if the oxide 410 is not used). The thickness of the poly 412 depends on the desired bottom oxide sidewall thickness T1, which may be between about 500 angstroms and about 5000 angstroms. The poly 412 may then be anisotropically etched back to form the poly spacers 413 as shown in FIG. 4D.

The oxide 408 is then anisotropically etched to a desired thickness T2 at the bottom as shown in FIG. 4E. The thickness of T2 may be between about 500 angstroms and about 5000 angstroms. The polysilicon that forms the spacers 413 is preferably resistant to the etch process used to anisotropically etch the oxide 408. The thickness of the poly spacer 413 on the sidewalls of the trench determines the thickness T1 therefore determines the width A″ of a trench etched into the oxide 408 by the anisotropic etch process. After etching, the spacer 413 may be removed as shown in FIG. 4F. The “aspect ratio” is effectively enlarged over the top portion of trench for easier gap fill than if a thick oxide were uniformly formed on the bottom and sidewalls of the trench. It is further noted that the bottom thickness T2 may be determined independently of the sidewall thickness T1 by simply varying the duration of the anisotropic etch. In general, it is desirable to form T2>T1.

Conductive material, such as polysilicon 414 may be deposited to fill the trench in the oxide 408 as shown in FIG. 4G. The polysilicon 414 may then be etched back to below the top surface of the thick oxide 408, e.g., by about 1000 Angstroms to 2000 Angstroms to form a gap 416 as shown in FIG. 4H. The remaining polysilicon 414 may act as a shield electrode for the finished device. An insulator, such as poly reoxidation (reox) 418 may be formed to fill the gap 416 as shown in FIG. 4I. The thickness of the poly reoxidation 418 may be about 2000 Angstroms to 3000 Angstroms. As the upper portion and the top surface are covered by nitride layer 406, no oxidation occurs in this area.

The optional thin oxide 410 may be etched following by etching off the exposed portions of nitride 406 and oxide 404 as shown in FIG. 4J.

Gate oxide 420 may then be grown on the sidewall of the trench and on top of the semiconductor substrate 402 as shown in FIG. 4K. Finally, conductive material, such as doped polysilicon 423 may be deposited to fill the top portion of the trench 401 and then etched back to form an active gate as shown in FIG. 4L. The thickness of the gate oxide 420 on the sidewalls of the top portion of the trench 401 determines a width A′ of a top portion of the active gate that is formed by the polysilicon 423. In general gate oxide 420 is much thinner than T1 and T2, in the range of tens to hundreds of Angstroms. Further the top surface of poly 423 may be recessed below oxide layer 420.

The fabrication of the device may continue with standard processes to implant body regions 430 and source regions 432, followed by the formation of a thick dielectric layer 460 on top of the surface and open contact holes through dielectric layer 460 for depositing a source metal 470 to electrically connect to the source and body regions. The device 400 resulting from this process as shown in FIG. 4M is constructed on a substrate 402 which comprising a lightly doped Epitaxial layer 402-E overlaying a heavily doped substrate layer 402-S. In the embodiment shown in FIG. 4M, gate trench 401 extends from the top surface of Epitaxial layer 402-E through the entire 402-E layer reach into substrate layer 402-S. Alternatively the bottom of trench 401 may stop within Epitaxial layer 402-E without reaching substrate layer 402-S (not shown). The trench 401 has a poly gate electrode 423 disposed in the upper portion of the trench and a poly shielding electrode 414 disposed in the lower portion of the trench with an inter poly dielectric layer 418 in between insulating the two. To optimize the shielding effect, the bottom shielding electrode may electrically connect through layout arrangement to the source metal layer 470 where a ground potential is usually applied in applications. A thin gate oxide layer 420 insulates the gate electrode from the source and body regions in the upper portion of trench. To minimize the gate to drain capacitance of the device therefore to improve the device switching speed and efficiency, body regions 430 is carefully controlled to diffuse to substantially the bottom of gate electrode 423 to effectively reduce the coupling between gate 423 and drain region disposed below the body regions. The bottom shielding (or source) electrode 414 is surrounded by a thick dielectric layer 424 along the lower sidewalls and the bottom of trench to insulate from the drain region. Preferably the dielectric layer 424 is much thicker than the thin gate oxide layer 420 and has a variable thickness that is T2 on the trench bottom and T1 on trench sidewalls, whereas T1<T2. As shown in FIG. 4M, dielectric layer 424 may further comprise a nitride layer 406 sandwiched between oxide layers 404 and 408.

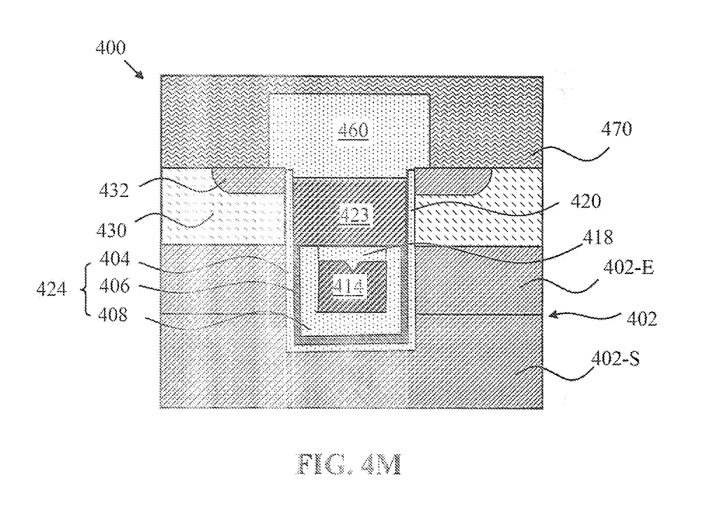

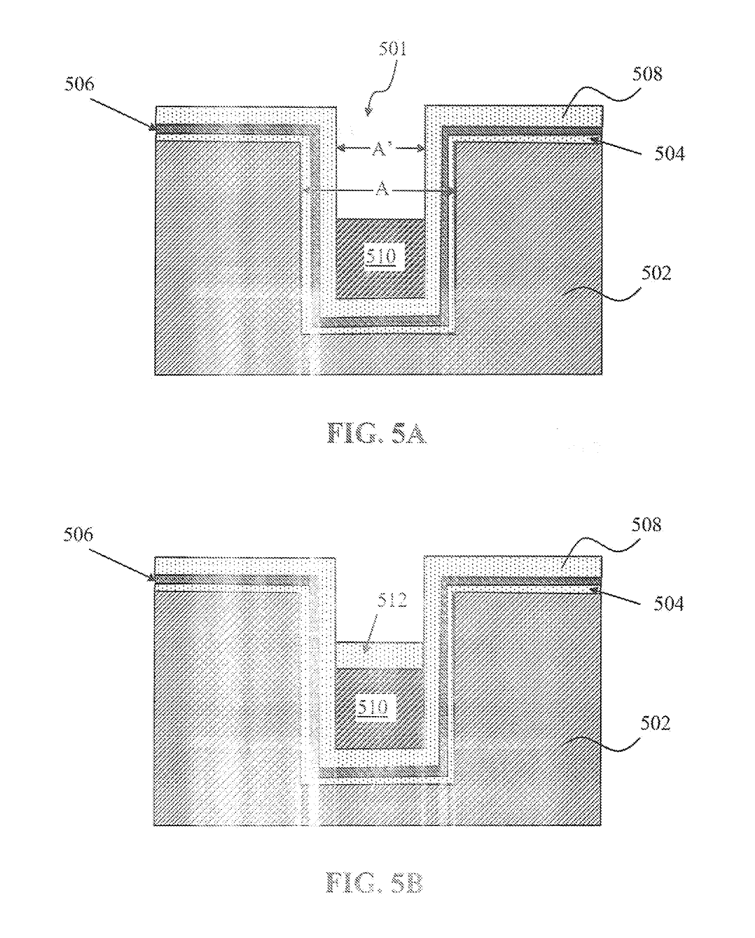

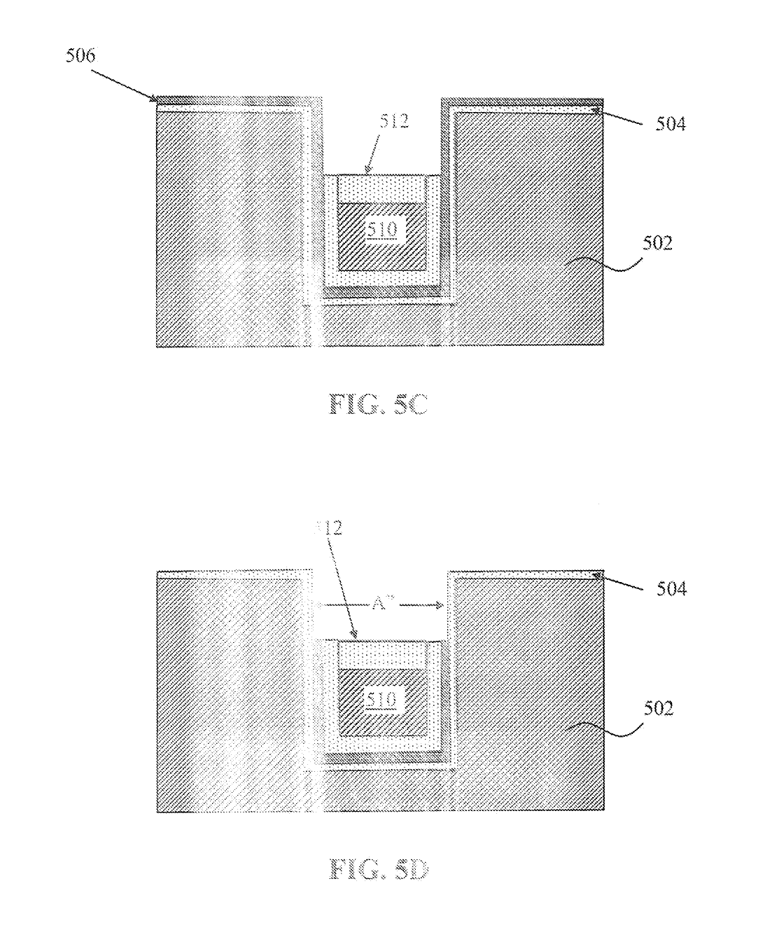

FIGS. 5A to 5F illustrate another alternative process of fabricating a trench DMOS with variable-thickness gate oxides for a shield poly gate of the type depicted in FIG. 2 according to an embodiment of the present invention.

As shown in FIG. 5A, a trench 501 of width A is formed in a semiconductor substrate 502. A thin insulator layer such as an oxide layer 504 is grown or deposited on the surfaces of the trench 501 and on the top surface of the semiconductor substrate 502. A thickness of the oxide 504 may be about 450 Angstroms. A layer of material such as a nitride 506 is then deposited, e.g., to a thickness between about 50 Angstroms and about 500 angstroms, on top of the oxide 504 followed by deposition of another oxide, e.g., HTO (high temperature oxide) oxide 508, on top of the nitride 506. The thickness of the nitride 506 may be about 100 Angstroms and the thickness of the HTO oxide 508 may be about 800 Angstroms. In this example, the combined thickness of the oxide 504, nitride 506 and HTO oxide 508 determines a width A′ of a narrowed trench 501. In-situ doped polysilicon 510 may then be deposited into the narrowed trench 501 and then etched back to a predetermined thickness of, e.g., between about 500 angstroms and about 2 microns to form a shield electrode. Arsenic may be optionally implanted into at least an upper portion of the polysilicon 510 remaining in the trench to enhance a re-oxidation rate of the polysilicon in a subsequent oxidation step.

Specifically, as shown in FIG. 5B, an insulator such as a poly reox layer 512 may be formed by the oxidation of a top portion of the polysilicon 510. The thickness of the poly reox 512 may be about 3000 Angstroms. The nitride layer 506 ensures that oxide layer 512 is only formed on top of the polysilicon 510. The HTO oxide 508 may then be removed by an etch process that stops on the nitride layer 506 as shown in FIG. 5C. This protects the underlying oxide 504 from the etch process that removes the thicker HTO oxide 508. The nitride 506 may then be removed leaving an upper portion of the trench with a width A″ that is wider than A′ as shown in FIG. 5D. In this example, the width A″ of the upper portion is determined by the thickness of the thin oxide 504 on the sidewalls of the trench. The thickness uniformity of the inter-poly oxide 512 across the wafer may be improved by use of a thermal oxide. This is because a thermal oxide process oxidizes the top portion of the poly in the trench as opposed to depositing and etching back the oxide on the poly in the trench.

The oxide can be preserved during the nitride removal process due to high nitride to oxide wet etch selectivity.

Gate oxide 514 may then be formed (e.g., by growth or deposition) on the thin oxide 504 as shown in FIG. 5E. The thickness of the gate oxide 514 may be about 450 Angstroms. Alternatively, the thin oxide 504 may first be removed before growing the gate oxide 514. Finally, a second conductive material, such as doped polysilicon 516, may be deposited into the remaining portions of the trench over the gate oxide 514. The polysilicon 516 may be etched back to form a shield gate structure, in which the polysilicon 516 is the gate electrode and the polysilicon 510 is the shield electrode.

It should be clear to those skilled in the art that in the embodiments described above, only a single mask—an initial mask used to define the gate trenches is required in the formation of the gate trench, gate trench oxides, gate poly, and shield poly.

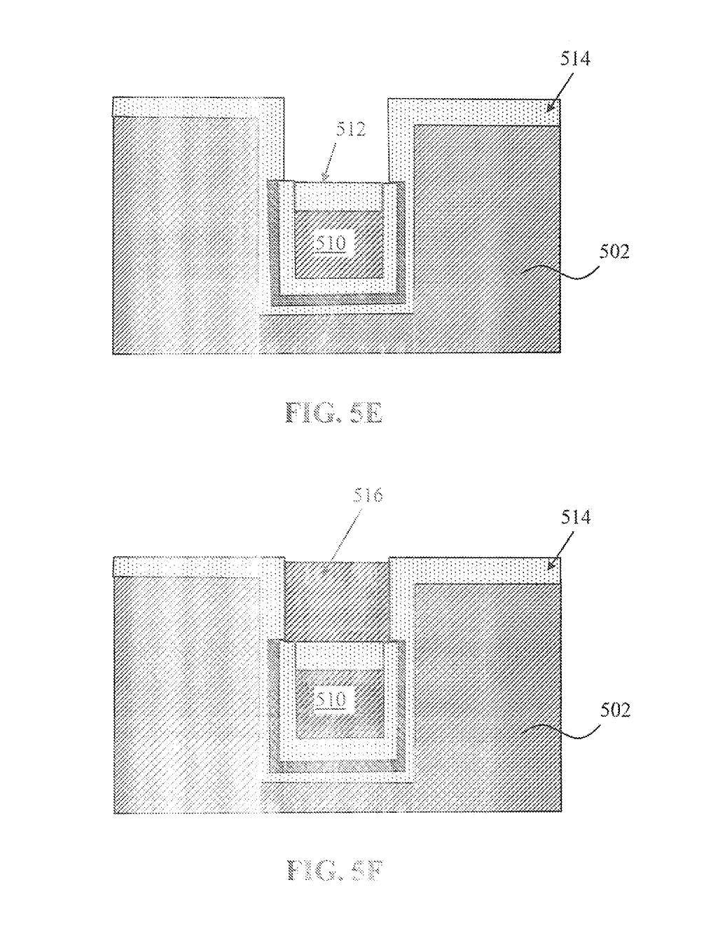

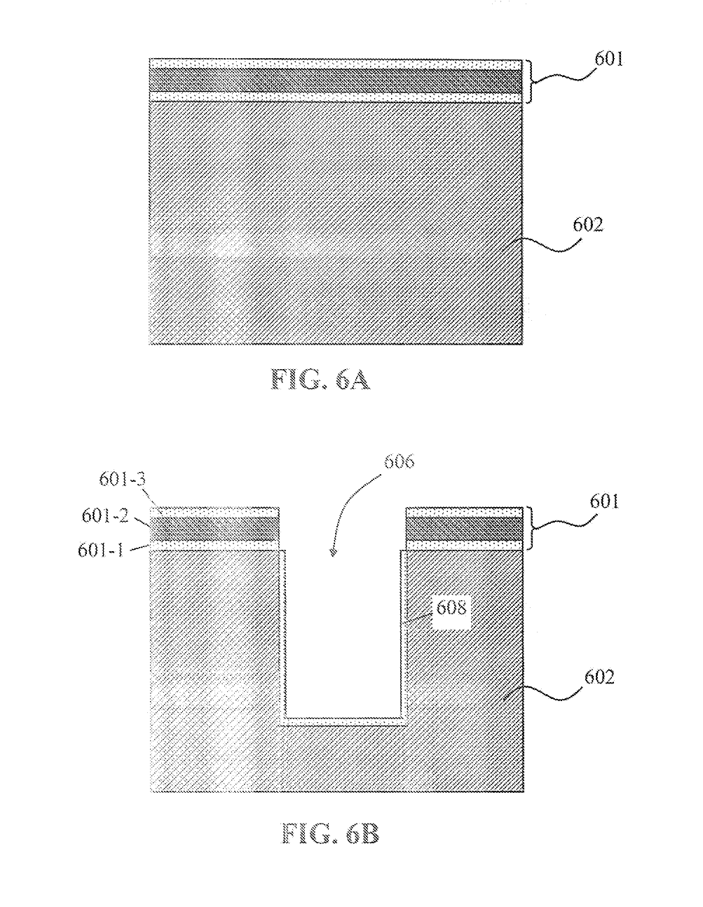

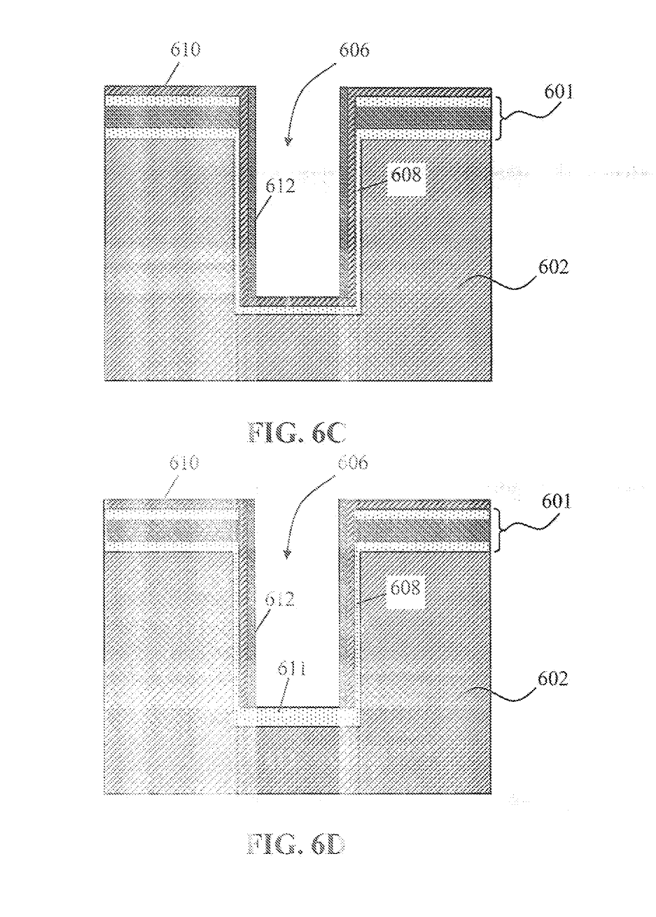

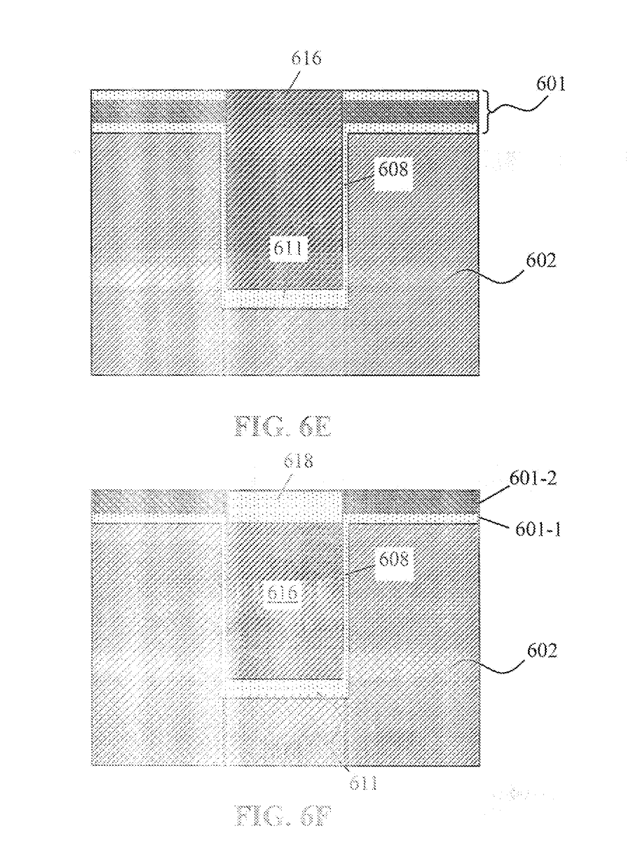

FIGS. 6A-6F are cross-sectional views illustrating the fabrication process steps for manufacturing a trench DMOS with variable-thickness trench gate oxides according to an embodiment of the present invention.

As shown in FIG. 6A, an ONO (oxide-nitride-oxide) hard mask 601 is formed on top of a semiconductor substrate 602, which includes a bottom oxide layer 601-1, a middle nitride layer 601-2 and a top oxide layer 601-3. By way of example and not by way of limitation, the bottom oxide layer 601-1 may be approximately 200 angstroms, the nitride layer 601-2 may be 3500 angstroms, and the top upper oxide layer 601-3 may be 1400 angstroms. In FIG. 6B, a trench mask (not shown) is applied to carry out a hard mask etch and silicon etch to form a trench 606 in the semiconductor substrate 602. In an exemplary embodiment, the trench etching process is carried out with a ratio of depth B, including the thickness of the hard mask 601, to width A, i.e., aspect ratio, B/A>3. A trench etching process may first comprise an etchant to remove the ONO hard mask 601, in order to expose the top surface of the semiconductor substrate 602 and a second etching process to form the trench 606. Then a thin gate oxide layer (or other insulator) 608 is grown along the sidewalls and on the bottom surface of the trench 606. In an exemplary embodiment, the thickness of the thin oxide 608 has a range between about 100 Angstroms to 600 Angstroms.

FIG. 6C shows a step of depositing a thin layer of polysilicon layer 610 over the gate oxide layer 608 that may have a thickness ranging between 100 to 800 Angstroms on the sidewalls and the bottom surface of the trench 606. Then a nitride layer 612 is deposited over the polysilicon layer 610. In an exemplary embodiment, the nitride layer 612 has a thickness ranging between 50 to 300 Angstroms. The nitride layer 612 on the bottom surface of the trench is removed with an etching process, for example a nitride dry etch process, to form a nitride spacer 612 along the sidewalls of the trench 606. In FIG. 6D, the manufacturing process proceeds with a polysilicon re-oxidation process, i.e., poly REOX, to oxidize the exposed bottom polysilicon layer 610 to form a bottom poly-REOX oxide layer that combines with the gate oxide layer 608 forming a thick bottom oxide layer 611 on the bottom surface of the trench 606.

In FIG. 6E, the nitride spacer 612 on the sidewalls of the trench 602 is removed by a wet dip and then the trench 606 is filled with a conductive material such as a polysilicon layer 616 for example through chemical vapor deposition (CVD). Excess polysilicon layer 616 is removed and planarized with the surface of the hard mask 601 by a chemical-mechanical planarization (CMP) process. In FIG. 6F, an poly etch back process is carried out to etch back the polysilicon layer 612 to the surface of the semiconductor substrate 602, for example with a dry etching process, to generate a poly-recess that is then filled with an oxide layer 618. Excess oxide layer 618 on top of the polysilicon layer 616 and the top oxide layer 601-3 of the hard mask 601 is then planarized by a CMP process to the surface of the nitride layer 601-2 of the hard mask 601. The device may be completed by a standard process to form a trench MOSFET that has a thick bottom oxide (TBO).

Although the present invention has been described in terms of the presently preferred embodiment, it is to be understood that such disclosure is not to be interpreted as limiting. For these embodiments, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

We claim:

1. A semiconductor device formed in a semiconductor substrate comprising:
a trench opened in the semiconductor substrate having a trench bottom surface covered by a first bottom insulation layer and a bottom poly-REOX oxide layer;
the trench further having sidewalls covered by a first sidewall insulation layer and further having a first polysilicon layer covering the first sidewall insulation layer; and
the trench is filled with a second polysilicon layer constituting a trench gate for the semiconductor device.

2. The semiconductor device of claim 1 wherein:
the first bottom insulation layer comprises a first bottom oxide layer and the first sidewall insulation layer comprises a first sidewall oxide layer.

3. The semiconductor device of claim 1 wherein:
the trench has an aspect ratio of trench depth/trench width (B/A)>3.

4. The semiconductor device of claim 1 wherein:
the first bottom insulation layer and the first sidewall insulation layer having a layer thickness ranging between 50 to 150 Angstroms.

5. The semiconductor device of claim 1 wherein:
the first bottom insulation layer comprises a first bottom oxide layer and the first sidewall insulation layer comprises a first sidewall oxide layer; and
the first bottom oxide layer and the first sidewall oxide layer having a layer thickness ranging between 50 to 150 Angstroms.

6. The semiconductor device of claim 1 wherein:
the bottom poly-REOX oxide layer covering the first bottom insulation layer having a layer thickness ranging between 200 Angstroms to 500 Angstroms.

7. The semiconductor device of claim 1 wherein:
the bottom poly-REOX oxide layer covering the first bottom insulation layer having a greater layer thickness than the sidewall insulation layer.

8. A method for manufacturing a semiconductor device in a semiconductor substrate comprising:
opening a trench in the semiconductor substrate and forming a first insulation layer covering trench sidewalls and a trench bottom surface;
depositing a first polysilicon layer covering over the first insulation layer on the trench bottom surface and the trench sidewalls;
depositing a protective spacer layer covering over the first polysilicon layer on the bottom surface and the trench sidewalls followed by a selective etching to etch the protective spacer layer to expose the first polysilicon layer on the trench bottom surface while covering the first polysilicon layer on trench sidewalls; and
carrying out a poly REOX process for oxidizing the exposed first polysilicon layer on the trench bottom surface forming a poly-REOX layer followed by removing the protective spacer layer from the trench sidewalls and filling the trench with a second polysilicon layer.

9. The method of claim 8 wherein:
the step of opening the trench in the semiconductor substrate comprising a step of forming an oxide-nitride-oxide (ONO) hard mask on top the semiconductor substrate and applying a trench mask to carry out a hard mask etch and a silicon etch to form the trench, the ONO hard mask comprises a bottom oxide layer, a middle nitride layer and a top oxide layer.

10. The method of claim 8 wherein:
the step of forming the protective spacer layer comprising a step of forming a silicon nitride layer.

11. The method of claim 8 wherein:
the step of forming the protective spacer layer comprising a step of forming a silicon nitride layer having a layer thickness ranging between 100 to 300 Angstroms.

12. The method of claim 8 wherein:
the step of forming the first insulation layer comprises a step of forming a first oxide layer to cover the trench bottom surface and the trench sidewalls.

13. The method of claim 8 wherein:
The step of opening the trench comprises a step of opening the trench having an aspect ratio of trench depth/trench width (B/A)>3.

14. The method of claim 8 wherein:
the step of forming the first insulation layer comprises a step of forming the first insulation layer having a layer thickness ranging between 50 to 150 Angstroms.

15. The method of claim 8 wherein:
the step of forming the first insulation layer further comprises a step of forming the first insulation layer as first oxide layer covering the trench sidewalls and the trench bottom surface having a layer thickness ranging between 50 to 150 Angstroms.

16. The method of claim 8 wherein:
the step of oxidizing the exposed first polysilicon layer form the poly-REOX layer comprises a step of oxidizing the exposed first polysilicon layer on the trench bottom surface to form the poly-REOX layer having a layer thickness ranging between 200 Angstroms to 500 Angstroms.

17. The method of claim 8 wherein:
the step of oxidizing the exposed first polysilicon layer to form the poly-REOX layer comprises a step of oxidizing the exposed first polysilicon layer on the trench bottom surface to form the poly-REOX layer having a greater layer thickness than the sidewall insulation layer.

18. The method of claim 9 further comprising:
performing a chemical-mechanical planarization (CMP) process to planarize the second polysilicon layer to the top surface of the hard mask.

19. The method of claim 18 further comprising:
performing a poly etch back process to etch back the second polysilicon layer to generate a poly-recess and filling the poly-recess with a top oxide layer on top of the second polysilicon layer followed by carrying out a CMP process to planarize the top oxide layer to the top surface of the middle nitride layer of the hard mask.

20. A semiconductor device formed in a semiconductor substrate comprising:
a trench opened in the semiconductor substrate having a thicker trench bottom oxide (TBO) wherein a trench bottom surface covered by a first bottom oxide layer and a bottom poly-REOX oxide layer.
